(19) United States
(12) Patent Application Publication
(10) Pub. No.: US 2014/0190636 A1
(43) Pub. Date: Jul. 10, 2014

(54) SUBSTRATE PROCESSING APPARATUS

(71) Applicant: SAMSUNG DISPLAY CO., LTD, Yongin-City (KR)

(72) Inventor: Dong-Seok Shin, Yongin-City (KR)

(73) Assignee: SAMSUNG DISPLAY CO., LTD, Yongin-City (KR)

(21) Appl. No.: 13/942,647

(22) Filed: Jul. 15, 2013

(30) Foreign Application Priority Data
Jan. 9, 2013 (KR) 10-2012-0002504

(51) Int. Cl. H01J 37/32

(52) U.S. Cl. CPC H01J 37/32009
USPC 156/345.51; 156/345.1; 118/723 R

(57) ABSTRACT

A substrate processing apparatus includes a processing chamber for processing a substrate, a shield at an inner wall of the processing chamber, and a connector attaching the shield to the inner wall of the processing chamber. The connector includes a groove and a protrusion respectively on opposing surfaces of the inner wall of the processing chamber and the shield.

### CROSS-REFERENCE TO RELATED PATENT APPLICATION

This application claims priority to and the benefit of Korean Patent Application No. 2012-0002504, filed on Jan. 9, 2013 in the Korean Intellectual Property Office (KIPO), the disclosure of which is incorporated herein in its entirety by reference.

### BACKGROUND

1. Field

Aspects of the present invention relate to a substrate processing apparatus.

2. Description of the Related Art

A substrate processing apparatus may be used to process a substrate such as a glass substrate to manufacture a flat display device. For example, the substrate processing apparatus may include a processing chamber for performing a plasma process therein and a shield member for removing particles to be deposited on an inner wall of the processing chamber.

A conventional shield member may be attached on the inner wall of the processing chamber by a fixing member such as a bolt. The bolt may penetrate the shield member to be coupled to a screw thread on the inner wall of the processing chamber such that the shield member is attached on the inner wall of the processing chamber. Further, a bolt cap may be provided to cover the bolt.

However, as the flat display device has become larger, the size of the processing chamber is increased, and thus, the size of the shield member and the number of the shield members are increased. Also, the number of fixing parts such as the bolts and the bolt caps may be increased. Accordingly, because the shield member is fixed by the fixing parts such as the bolts, attaching and detaching of the shield members on the inner wall of the processing chamber will be more time consuming. Further, the fixing parts may be more likely to be damaged due to differences in the coefficient of thermal expansion of different fixing parts. Additionally, a plasma arc may occur due to a gap between the shield member and the inner wall of the processing chamber during a plasma etching process.

### SUMMARY

Example embodiments provide a substrate processing apparatus including a shield member capable of being detachably attached to an inner wall of a processing chamber.

According to example embodiments, a substrate processing apparatus includes a processing chamber for processing a substrate, a shield at an inner wall of the processing chamber, and a connector attaching the shield to the inner wall of the processing chamber. The connector includes a groove and a protrusion respectively on opposing surfaces of the inner wall of the processing chamber respectively and the shield.

In example embodiments, the groove of the connector may include a dovetail groove extending along a surface of the shield, and the protrusion of the connector may include a dovetail extending along an inner wall of the processing chamber corresponding to the dovetail groove.

In example embodiments, the dovetail may have an outer sidewall that forms an angle less than 90 degrees with respect to the inner wall of the processing chamber.

In example embodiments, the connector may include a fixing member configured to couple the dovetail to the inner wall of the processing chamber.

In example embodiments, the shield may include a protruding portion having a first thickness and a recessed portion having a second thickness less than the first thickness, and the dovetail groove may be in the protruding portion of the shield.

In example embodiments, the first thickness may be in a range of about 10 mm to about 6 mm, and the second thickness may be in a range of about 6 mm to about 3 mm.

In example embodiments, the groove of the connector may include a dovetail groove extending along the inner wall of the processing chamber, and the protrusion of the connector may include a dovetail extending along the shield corresponding to the dovetail groove.

In example embodiments, the shield may include an upper shield at an upper inner wall of the processing chamber and a lower shield at a lower inner wall of the processing chamber.

In example embodiments, the shield may include aluminum.

In example embodiments, the substrate processing apparatus may further include a substrate stage configured to hold the substrate.

In example embodiments, the groove of the connector may extend from a lower surface of the shield in a first direction, and the protrusion of the connector may protrude from a bottom face of the processing chamber.

In example embodiments, the connector may detachably attach the shield to the inner wall of the processing chamber.

In example embodiments, the groove and the protrusion may be slidably fitted to each other.

According to example embodiments, the shield as a double shield may be assembled and disassembled to/from the chamber at once by a sliding fitting method without a conventional fixing part such as a bolt. Accordingly, a time required to clean the shield may be decreased and a manufacturing cost may be reduced.

### BRIEF DESCRIPTION OF THE DRAWINGS

Example embodiments will be more clearly understood from the following detailed description taken in conjunction with the accompanying drawings. FIGS. 1 to 7 represent non-limiting, example embodiments as described herein.

FIG. 1 is a cross-sectional view illustrating a substrate processing apparatus in accordance with example embodiments.

FIG. 2 is a perspective view illustrating a shield member attached to an inner wall of a processing chamber of the substrate processing apparatus in FIG. 1.

FIG. 3 is a cross-sectional view of a portion marked by a dotted circle “A” in FIG. 2.

FIG. 4 is a perspective view illustrating a dovetail on the inner wall of the processing chamber in FIG. 2.

FIG. 5 is a perspective view illustrating a shield member of a substrate processing device in accordance with example embodiments.

FIG. 6 is a perspective view illustrating a shield member of a substrate processing apparatus in accordance with example embodiments.

FIG. 7 is a perspective view illustrating a method of maintaining a substrate processing apparatus in accordance with example embodiments.

### DETAILED DESCRIPTION OF EXAMPLE EMBODIMENTS

Various example embodiments will be described more fully hereinafter with reference to the accompanying drawings, in which example embodiments are shown. Example embodiments may, however, be embodied in many different forms and should not be construed as limited to example embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

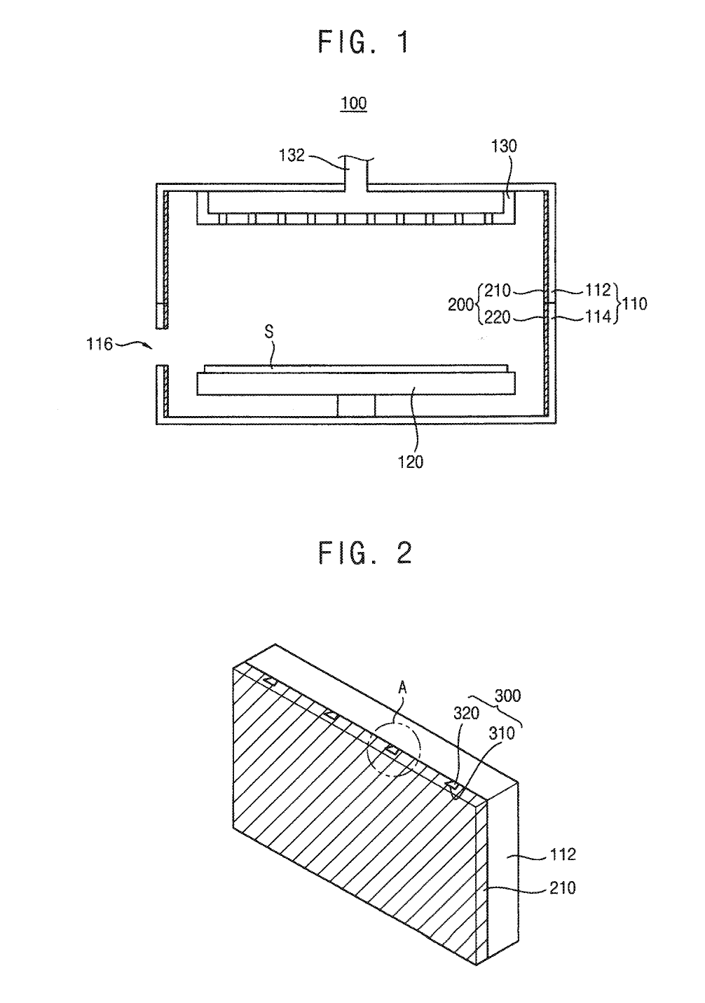

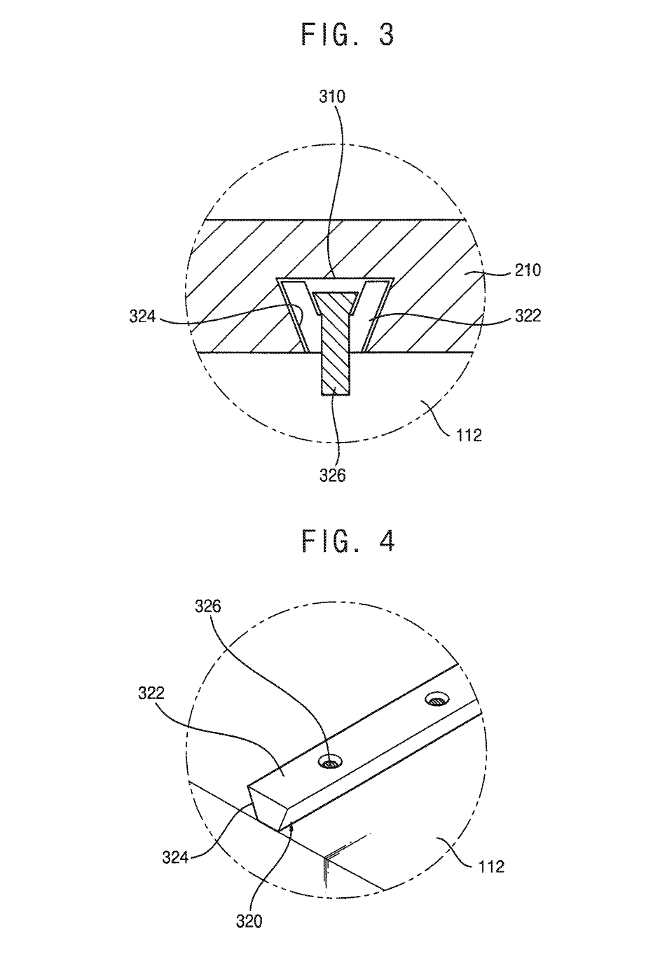

FIG. 1 is a cross-sectional view illustrating a substrate processing apparatus in accordance with example embodiments. FIG. 2 is a perspective view illustrating a shield member attached to an inner wall of a processing chamber of the substrate processing apparatus in FIG. 1. FIG. 3 is a cross-sectional view illustrating the portion of the substrate processing apparatus labeled with the letter “A” in FIG. 2. FIG. 4 is a perspective view illustrating a dovetailed protrusion formed on the inner wall of the processing chamber in FIG. 2.

Referring to FIGS. 1 to 4, a substrate processing apparatus 100 may include a processing chamber 110 for processing a substrate S, a substrate stage 120 for holding the substrate S in the processing chamber 110, a shield (or shield member) 200 provided to cover an inner wall of the processing chamber 110, and a connector (or connecting part) 300 for detachably attaching the shield member 200 to the inner wall of the processing chamber 110.

In example embodiments, the substrate processing apparatus 100 may perform a plasma process on the substrate S such as a display panel in the processing chamber 110. The substrate processing apparatus 100 may include a shower head or dispenser 130 for supplying a processing gas to the substrate S that is loaded through a gate 116. For example, a depositing gas or etching gas may flow through a gas supplying line 132, and the shower head 130 may substantially uniformly distribute the processing gas into the processing chamber 110.

In order to generate plasma of radicals from the processing gas in the processing chamber 110, a plasma electrode (not illustrated) may be provided in an upper portion of the processing chamber 110 and the substrate stage 120 to supply a high frequency power.

In example embodiments, the processing chamber 110 may include an upper chamber 112 and a lower chamber 114 that are combined or coupled together to form a vacuum space. The shied member 200 may include an upper shield member 210 covering an inner wall of the upper chamber 112 and a lower shield member 220 covering an inner wall of the lower chamber 114.

The upper shield member 210 and the lower shield member 220 may be substantially the same as each other except for the installation positions and the sizes thereof. The shield member 200 may include a ceramic coated aluminum plate or an anodized aluminum plate.

As shown in FIG. 2, the upper shield member 210 may be detachably attached (or coupled) to the inner wall of the upper chamber 112 by the connecting part 300. Additionally, depending on the size and shape of the upper chamber 112 and the upper shield member 210, two upper shield members 210 may be attached to each side wall of the upper chamber 112 such that a total of eight upper shield members may be attached (or coupled) to the entire inner wall (e.g., two upper shield members 210 detachably attached (or coupled) to each plane of the inner wall) of the upper chamber 112. However, the number of the upper shied members should not be limited thereto, the number of the upper shield members may vary according to the size and shape of the upper chamber 112. Similarly, the lower shield member 220 may be detachably attached or coupled to the inner wall of the lower chamber 114 by the connecting part 300. The number of the lower shield members 220 detachably attached or coupled to the lower chamber 114 may vary according to the size and shape of the lower chamber 114.

The connecting part 300 may include a groove and a protrusion that are provided on opposing surfaces of the shield member 200 and the inner wall of the processing chamber 110, respectively, and are slidably fitted to each other. As illustrated in FIGS. 2 to 4, the groove of the connecting part 300 may be a dovetail groove 310 extending in a first direction along the surface of the shield member 200. The protrusion of the connecting part 300 may be a dovetail 320 extending in the inner wall of the upper chamber 112 corresponding to the dovetail groove 310.

As illustrated in FIGS. 3 and 4, the dovetail 320 may include an insertion portion 322 extending in the first direction. The first direction may be parallel with a vertical direction of the processing chamber 110. The insertion portion 322 of the dovetail 320 may have opposing outer sidewalls 324 and an upper surface connecting (or coupled between) the outer sidewalls 324. The outer sidewall 324 may form an angle less than 90 degrees with respect to the inner wall of the upper chamber 112.

The connecting part 300 may include a fixing member 326 for fixing the insertion portion 322 on the inner wall of the upper chamber 112. The fixing member 326 may include a fixing bolt. An upper surface of the fixing member 326 may be lower than (e.g., vertically offset with respect to) the upper surface of the insertion portion 322 of the dovetail 320, as shown in FIG. 3. Alternatively, the insertion portion 322 may be integrally formed with the inner wall of the processing chamber 110. In this case, a plurality of the dovetails 320 may be formed with the chamber 110.

The upper shield member 210 may be jointed to the upper chamber 112 using a sliding dovetail method by the connecting part 300. The dovetail 320 may be slidably fitted into the dovetail groove 310 in the first direction, such that the upper shield member 210 is attached on the inner wall of the upper chamber 112. The dovetail 320 may be extracted from the dovetail groove 310 in the opposite direction, such that the upper shield member 210 is detached from the inner wall of the upper chamber 112. Accordingly, the upper shield member 210 may be detachably attached to the inner wall of the upper chamber 112 by the connecting part 300.

The dovetail groove 310 may be formed to be slightly tapered, making it slightly tighter towards the rear of the dovetail groove 310, so that the upper shield member 210 may be slid easily into the dovetail 320 but the joint becomes tighter as the finished position is reached. That is, a gap between opposing sidewalls of the dovetail groove 310 may be wider at the deepest point of the dovetail groove 310, and narrower at the opening of the dovetail groove 310.

Accordingly, the shield member 200 as a double shield may be assembled and disassembled to/from the chamber by a sliding fitting method without a conventional fixing part such as a bolt. Accordingly, a time required to clean the shield member may be decreased and a manufacturing cost may be reduced.

As illustrated in FIGS. 2 to 4, the dovetail groove 310 may be formed in the shield member 200 and the dovetail 320 may be formed in the inner wall of the processing chamber 110. Alternatively, the dovetail groove 310 may be formed in the surface of the inner wall of the processing chamber 110 and the dovetail 320 may be formed in the surface of the shield member 200 corresponding to the dovetail groove.

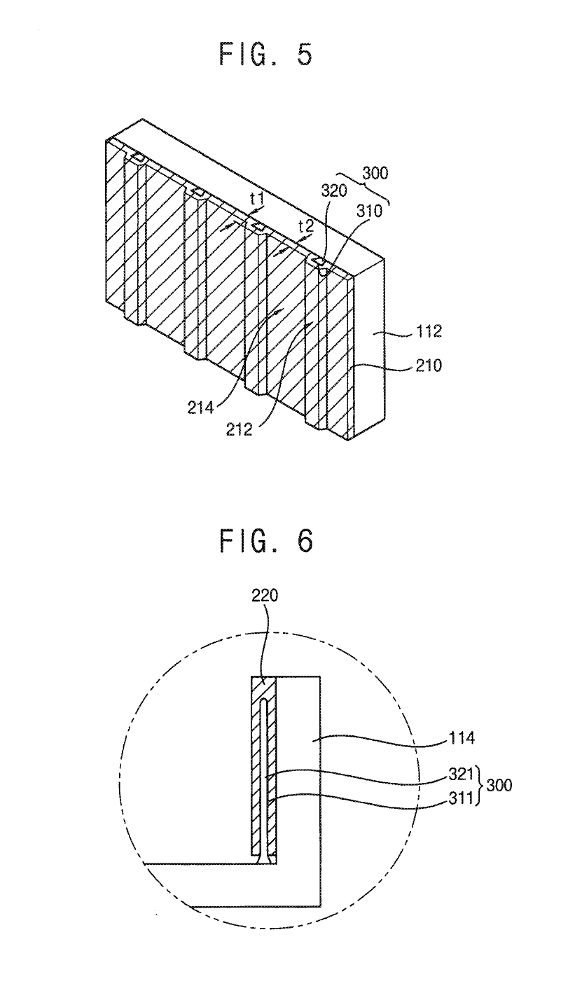

FIG. 5 is a perspective view illustrating a shield member of a substrate processing device in accordance with example embodiments. The shield member is substantially the same as the shield member described with reference to FIG. 1, except for a protruding shape thereof. Thus, the same or like reference numerals will be used to refer to as the same or like elements and any repetitive explanation concerning the above elements will be omitted.

Referring to FIG. 5, the upper shield member 210 may be detachably attached to the inner wall of the upper chamber 112 by the connecting part 300. The upper shield member 210 may include a protruding portion 212 and a recessed portion 214. The protruding portion 212 may have a first thickness t1, and the recessed portion 214 may have a second thickness t2 less than the first thickness t1. For example, the first thickness t1 may be from 10 mm to 6 mm, and the second thickness t2 may be from 6 mm to 3 mm.

The dovetail groove 310 may extend along the protruding portion 212 of the upper shield member 210. The dovetail 320 may extend along the surface of the inner wall of the upper chamber 112 corresponding to the dovetail groove 310.

FIG. 6 is a perspective view illustrating a shield member of a substrate processing apparatus in accordance with example embodiments. The shield member is substantially the same as the shield member described with reference to FIG. 1, except a fixing type thereof. Accordingly, the same or like reference numerals will be used to refer to as the same or like elements and any further repetitive explanation concerning the above elements will be omitted.

Referring to FIG. 6, the lower shield member 220 may be detachably attached to the inner wall of the lower chamber 114 by the connecting part 300. The lower shield member 220 may include a groove 311 extending from a lower surface of the lower shield member facing a bottom face of the chamber 110. The groove 311 may extend from the lower surface to a particular depth (e.g., a predetermined depth) in the first direction, that is, a vertical direction of the chamber 110. The protrusion 321 may protrude or extend from the bottom face of the chamber 110 and may be configured to be inserted into the groove 311.

Accordingly, the protrusion 321 may be configured to be inserted into the groove 311 of the lower shield member 200 in the vertical direction, to cover the inner wall of the lower chamber 114.

Hereinafter, a method of maintaining the substrate processing apparatus in FIG. 1 will be explained.

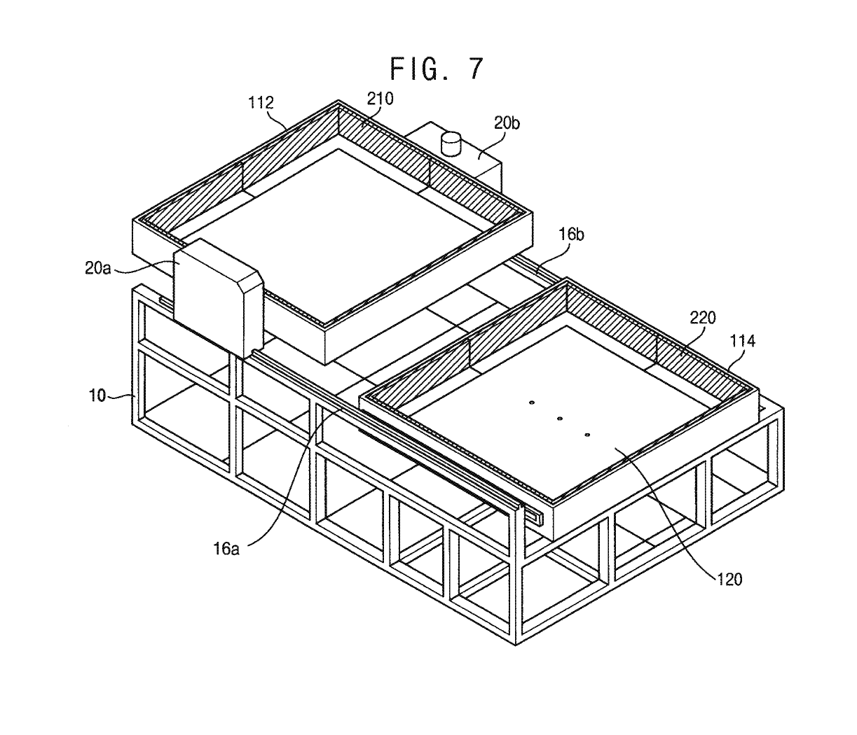

FIG. 7 is a perspective view illustrating a method of maintaining a substrate processing apparatus in accordance with example embodiments.

Referring to FIGS. 1 and 7, when processes are performed repeatedly in the processing chamber, undesired particles or contaminants may be deposited to form a thin layer on the shield member 200 on the inner wall of the processing chamber 110. In order to prevent or reduce delamination of the thin layer, the equipment in FIG. 7 may be used to clean the shield member 200.

In particular, the processing chamber 110 may be disassembled into the upper chamber 112 and the lower chamber 114 on a frame 10 in FIG. 7. Then, the dovetail may be extracted in the opposing direction of the inserting direction from the dovetail groove 310, such that the upper shield member 210 and the lower shield member 220 may be detached from the inner walls of the upper chamber 112 and the lower chamber 114. Accordingly, the shield members may be concurrently disassembled from the processing chamber 110.

Then, the separate shield members may be cleaned by a cleaning process. For example, the shield members may be cleaned by a wet cleaning process.

After the cleaning process, the dovetail may be slidably inserted into the dovetail groove, such that the upper shield member 210 and the lower shield member 220 may be attached on the inner walls of the upper chamber 112 and the lower chamber 114. Accordingly, the shield members may be concurrently assembled to the processing chamber 110.

Then, the upper chamber 112 may be rotated 180 degrees by driving parts 20a, 20b in FIG. 7, transferred along guide rails 16a, 16b, and positioned on the lower chamber 114. The upper chamber 112 and the lower chamber 114 may be assembled to collectively constitute the processing chamber 110.

The present invention may be applied to a substrate processing apparatus for processing a substrate such as a semiconductor wafer and a glass substrate for a flat display device.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims and their equivalents.

What is claimed is:

1. A substrate processing apparatus comprising:
a processing chamber for processing a substrate;
a shield at an inner wall of the processing chamber; and
a connector attaching the shield to the inner wall of the processing chamber, the connector including a groove and a protrusion respectively on opposing surfaces of the inner wall of the processing chamber and the shield.

2. The substrate processing apparatus of claim 1, wherein the groove of the connector comprises a dovetail groove extending along a surface of the shield, and the protrusion of the connector comprises a dovetail extending along an inner wall of the processing chamber corresponding to the dovetail groove.

3. The substrate processing apparatus of claim 2, wherein the dovetail has an outer sidewall that forms an angle less than 90 degrees with respect to the inner wall of the processing chamber.

4. The substrate processing apparatus of claim 3, wherein the connector comprises a fixing member configured to couple the dovetail to the inner wall of the processing chamber.

5. The substrate processing apparatus of claim 2, wherein the shield comprises a protruding portion having a first thickness and a recessed portion having a second thickness less than the first thickness, and the dovetail groove is in the protruding portion of the shield.

6. The substrate processing apparatus of claim 5, wherein the first thickness is in a range of 10 mm to 6 mm, and the second thickness is in a range of about 6 mm to about 3 mm.

7. The substrate processing apparatus of claim 1, wherein the groove of the connector comprises a dovetail groove extending along the inner wall of the processing chamber, and the protrusion of the connector comprises a dovetail extending along the shield corresponding to the dovetail groove.

8. The substrate processing apparatus of claim 1, wherein the shield comprises an upper shield at an upper inner wall of the processing chamber and a lower shield at a lower inner wall of the processing chamber.

9. The substrate processing apparatus of claim 1, wherein the shield comprises aluminum.

10. The substrate processing apparatus of claim 1, further comprising a substrate stage configured to hold the substrate.

11. The substrate processing apparatus of claim 1, wherein the groove of the connector extends from a lower surface of the shield in a first direction, and the protrusion of the connector protrudes from a bottom face of the processing chamber.

12. The substrate processing apparatus of claim 1, wherein the connector detachably attaches the shield to the inner wall of the processing chamber.

13. The substrate processing apparatus of claim 1, wherein the groove and the protrusion are slidably fitted to each other.
